(19) United States
(12) Patent Application Publication
(10) Pub. No.: US 2026/0189853 A1
(43) Pub. Date: Jul. 2, 2026

(54) VIBRATION DRIVING APPARATUS

(71) Applicant: LG Display Co., Ltd., Seoul (KR)

(72) Inventors: YongWoo LEE, Paju-si (KR); MinKyu CHOI, Paju-si (KR); Seonwook LEE, Paju-si (KR); Sungtae LEE, Paju-si (KR)

(73) Assignee: LG Display Co., Ltd., Seoul (KR)

(21) Appl. No.: 19/208,395

(22) Filed: May 14, 2025

(30) Foreign Application Priority Data
Dec. 27, 2024 (KR) 10-2024-0198278

(51) Int. Cl. H04R 9/04; H04R 9/02; H04R 9/06; H10N 30/20; H10N 30/88

(52) U.S. Cl. CPC H04R 9/045; H04R 9/025; H04R 9/06; H10N 30/20; H10N 30/88; H04R 2499/15

(57) ABSTRACT

A vibration driving apparatus comprises a vibration member and a vibration apparatus configured to vibrate the vibration member to generate sound. The vibration apparatus includes a sound generating module and at least one vibration module connected to the sound generating module. The sound generating module may generate vibrations based on a supplied current, while the vibration module may include a film-type piezoelectric structure that vibrates based on a drive signal. The vibration apparatus may be on a rear surface of the vibration member such that sound is emitted from a front surface of the apparatus. Integration of the sound generating module and the vibration module may enhance sound pressure level characteristics across mid to high frequency bands and enable multi-panel sound output. This configuration may reduce structural complexity, improve reliability, and simplify manufacturing by allowing the vibration apparatus to function both as a sound source and as a vibration actuator.

### CROSS-REFERENCE TO RELATED APPLICATION

This application claims the benefit of and priority to Korean Patent Application No. 10-2024-0198278 filed on Dec. 27, 2024, the entirety of which is hereby incorporated by reference for all purposes as if fully set forth herein. tairn

### BACKGROUND

### Technical Field

The present disclosure relates to a vibration driving apparatus.

### Description of the Related Art

An apparatus such as a display apparatus must install a separate speaker to provide sound. When a speaker is disposed on a display apparatus, since the speaker occupies a space, a problem occurs in that the design and space arrangement of the display device are restricted.

Since the sound output from the speaker travels backward or downward of the apparatus, there is a problem of poor sound quality due to interference between sounds reflected from a wall or a ground.

### BRIEF SUMMARY

The inventors of the present disclosure have recognized the problems and disadvantages of the related art and have performed extensive research and experiments to realize an apparatus capable of enhancing sound quality and having reliability. Based on the extensive research and experiments, the inventors have provided various embodiments of a vibration driving apparatus having a new structure capable of enhancing sound quality and enhancing reliability.

For instance, the disclosed vibration driving apparatus integrates a sound generating module and a piezoelectric vibration module to directly emit sound from a display panel, eliminating the need for conventional speakers. This integration improves sound characteristics, especially in the mid to low and mid to high frequency ranges, while simplifying the overall structure, reducing manufacturing complexity, and enabling a thinner and more flexible device design. The apparatus supports multi-panel sound output with spatial separation such as stereo sound, and its use of thermally efficient and lightweight materials such as polyimide film and aluminum coil enhances durability and thermal stability.

The apparatus also features a film type piezoelectric vibration module with layered electrodes and an embedded signal supply structure, allowing for precise vibration in both vertical and horizontal directions and efficient delivery of drive signals. Foam based adhesive components support the alignment and attachment of the modules, enabling straightforward assembly and consistent acoustic performance across a wide range of display types, including flexible OLED and LCD panels.

One or more aspects of the present disclosure are directed to providing a vibration driving apparatus including a vibration apparatus configured on a rear surface of a vibration member and capable of generating sound by vibrating the vibration member, and capable of improving sound pressure level characteristics.

One or more aspects of the present disclosure are directed to providing a vibration driving apparatus including a vibration apparatus capable of implementing multi-panel sound.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description as well as the appended drawings.

To achieve these and other advantages and aspects of the present disclosure, as embodied and broadly described herein, in one or more aspects, a vibration driving apparatus may comprise a vibration member, and a vibration apparatus configured to vibrate the vibration member. The vibration apparatus may include a sound generating module, and at least one vibration module connected to the sound generating module.

Details of other exemplary embodiments will be included in the detailed description of the disclosure and the accompanying drawings.

According to one or more embodiments of the present disclosure, the vibration driving apparatus includes the vibration apparatus which is configured at a rear surface of the vibration member, thereby vibrating the vibration member, and thus, sound may be generated to a front surface of the vibration driving apparatus.

According to one or more embodiments of the present disclosure, the vibration driving apparatus includes a sound generating module and a vibration apparatus in which the vibration module is integrated, and thus, sound characteristics and/or sound pressure level characteristics of the middle-low-pitched sound band and middle-high-pitched sound band may be improved.

According to one or more embodiments of the present disclosure, the vibration driving apparatus includes a sound generating module and a vibration apparatus in which the vibration module is integrated, and thus, the vibration driving apparatus has an effect of uni materialization.

According to one or more embodiments of the present disclosure, the vibration driving apparatus may simplify the structure of the vibration driving apparatus and reduce manufacturing costs by including a sound generating module and a vibration apparatus in which the vibration module is integrated.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is a diagram illustrating a vibration driving apparatus according to an embodiment of the present disclosure.

FIG. 2 is a diagram illustrating a vibration driving apparatus according to an embodiment of the present disclosure.

FIG. 3 is a cross-sectional view taken along line I-I′ illustrated in FIG. 2.

FIG. 4 is a cross-sectional view of a vibration apparatus illustrated in FIG. 3.

FIG. 5 is a diagram illustrating a vibration module according to an embodiment of the present disclosure.

FIG. 6 is a cross-sectional view taken along line II-II′ illustrated in FIG. 5.

FIG. 7 is a cross-sectional view of a vibration apparatus according to another embodiment of the present disclosure.

FIG. 8 is a cross-sectional view of a vibration apparatus according to another embodiment of the present disclosure.

FIG. 9 is a cross-sectional view of a vibration apparatus according to another embodiment of the present disclosure.

FIG. 10 is a diagram illustrating a vibration driving apparatus according to another embodiment of the present disclosure.

FIG. 11 is a cross-sectional view taken along line III-III′ illustrated in FIG. 10.

FIG. 12 is a cross-sectional view of the vibration apparatus illustrated in FIG. 11.

FIG. 13 is a diagram illustrating sound output characteristics of a vibration driving apparatus according to an embodiment of the present disclosure.

Throughout the drawings and the detailed description, unless otherwise described, the same drawing reference numerals should be understood to refer to the same elements, features, and structures.

### DETAILED DESCRIPTION

Advantages and features of the present disclosure, and implementation methods thereof, will be clarified through following embodiments described with reference to the accompanying drawings. The present disclosure may, however, be embodied in different forms and should not be construed as limited to the embodiments set forth herein. Rather, these embodiments are provided so that this disclosure is thorough and complete and fully conveys the scope of the present disclosure to those skilled in the art. Furthermore, the present disclosure is only defined by claims and their equivalents.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure aspects of the present disclosure, the detailed description may be omitted. Where the terms “comprise”, “have”, “make up of” and the like are used, one or more other elements may be added unless the term, such as “only” is used. The terms of a singular form may include plural forms unless the context clearly indicates otherwise.

In construing an element, the element is construed as including an error or tolerance range even where no explicit description of such an error or tolerance range is provided.

Where positional relationships are described, for example, where the positional relationship between two parts is described using “on”, “over”, “under”, “next to,” or the like, one or more other parts may be located between the two parts unless a more limiting term, such as “immediate(ly)” or “direct(ly)” is used.

It will be understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, sequence, order, or number of the elements. The expression that an element is “connected,” “coupled,” or “contacted” to another element, the element may not only be directly connected or adhered to another element, but also be indirectly connected or adhered to another element with one or more intervening elements interposed between the elements, unless otherwise specified.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

As used herein, the term “penetrate” refers to a structure or element entering into another material, layer, or region, and may encompass both partial entry (i.e., extending into) and complete traversal (i.e., extending through). The term does not require full passage through the entirety of the target structure, but includes any degree of entry sufficient to establish functional or structural interaction, whether by partial intrusion, full perforation, or continuity across multiple layers.

In the present disclosure, a vibration driving apparatus may include a display apparatus such as a display module (or a display member) including a display panel and a driver for driving the display panel. In addition, the display module may include a set device (or a set apparatus) or a set electronic device such as a notebook computer, a TV, a computer monitor, an equipment apparatus including an automotive apparatus or another type apparatus for vehicles, or a mobile electronic device such as a smartphone or an electronic pad, which is a complete product (or a final product) including a display module such as a liquid crystal display module and a light emitting display module (for example, an organic light emitting display module) or the like.

Therefore, in the present disclosure, the vibration driving apparatus in the present disclosure may include a display apparatus itself, such as the liquid crystal display module and the organic light emitting display module, or the like, and a set device which is a final consumer device or an application product including the liquid crystal display module and the organic light emitting display module.

In the present disclosure, the vibration driving apparatus including a vibration apparatus may be implemented as a user interface device such as a central control panel for automobiles and may be applied to vehicles. For example,

the user interface device for the vehicle may be configured between occupants sitting on two front seats so that sound generated by vibrations of the display module propagates toward the interior of the vehicle. Therefore, an audio experience in a vehicle is improved in comparison with a case where speakers are disposed on interior sides of the vehicle.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

Hereinafter, embodiments of the present disclosure will be described in detail with reference to the accompanying drawings. For convenience of description, a scale of each of elements illustrated in the accompanying drawings differs from a real scale, and thus, is not limited to a scale illustrated in the drawings.

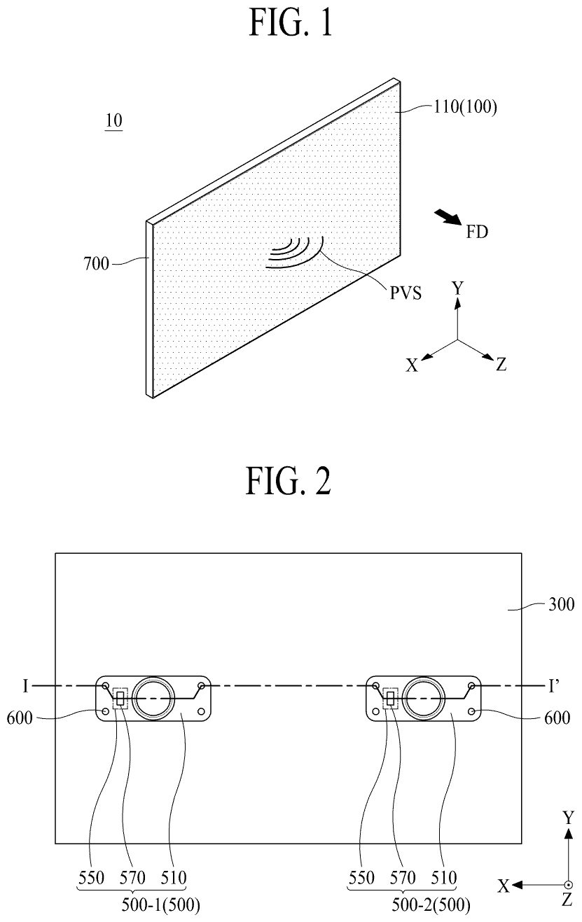

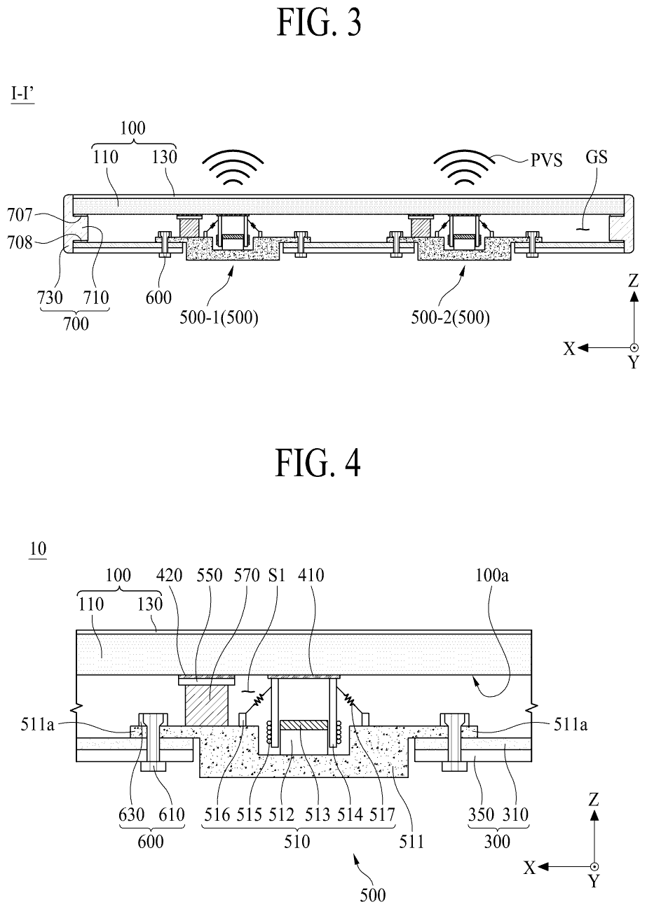

FIG. 1 is a diagram illustrating a vibration driving apparatus according to an embodiment of the present disclosure. FIG. 2 is a diagram illustrating a vibration driving apparatus according to an embodiment of the present disclosure. FIG. 3 is a cross-sectional view taken along line I-I′ illustrated in FIG. 2. FIG. 4 is a cross-sectional view of a vibration apparatus illustrated in FIG. 3.

Referring to FIGS. 1 to 4, a vibration driving apparatus 10 according to an embodiment of the present disclosure may include a vibration member 100, a rear cover 300, a vibration apparatus (or at least one or more vibration apparatuses) 500, and a middle frame 700.

The vibration member 100 may vibrate based on the driving of the at least one or more vibration apparatuses 500 while displaying an image, thereby outputting sound PVS (or panel vibration sound) in the forward direction FD. The vibration member 100 may vibrate based on the driving of the at least one or more vibration apparatuses 500 without displaying an image, outputting sound PVS in the forward direction FD. Accordingly, the vibration member 100 according to the present disclosure may simultaneously display an image and generate (or output) sound PVS.

The vibration member 100 may include a display panel 110 and a functional film 130.

The display panel 110 may display an image. For example, the image may include an electronic image or a digital image. For example, the display panel 110 may output light to display an image. The display panel 110 may be any type of display panel or curved display panel such as a liquid crystal display panel, an organic light emitting display panel, a quantum dot light emitting display panel, a micro light emitting diode display panel, and an electrophoretic display panel. The display panel 110 may be a flexible display panel. For example, the display panel 110 may be a flexible light emitting display panel, a flexible electrophoretic display panel, a flexible electronic wet display panel, a flexible micro light emitting diode display panel, or a flexible quantum dot light emitting display panel, but is not limited thereto.

The display panel 110 vibrates based on the vibration of the vibration apparatus 500 to directly output the sound PVS to the front FD, and thus, the display panel 110 may be a vibration plate (or a diaphragm) or a speaker that directly generates the sound PVS. For example, when the vibration member 100 generates the sound PVS, the vibration member 100 may be a vibration plate (or a diaphragm), a panel speaker, or a flat speaker that directly generates the sound PVS.

According to an embodiment of the present disclosure, the display panel 110 may include a pixel circuit disposed on a substrate (or a base substrate), and a pixel array layer (or a display part) connected to the pixel circuit and having an anode electrode, a cathode electrode, and a light emitting layer. The anode electrode may be a first electrode, a pixel electrode, or the like, but is not limited thereto. The cathode electrode may be a second electrode, a common electrode, or the like, but is not limited thereto. The display panel 110 may display an image in the form of a top emission type, a bottom emission type, or a dual emission type based on a structure of the pixel array layer. The top emission type may display an image by emitting visible light generated from the pixel array layer to a front direction of the substrate of the display panel 110. The bottom emission type may display an image by emitting visible light generated from the pixel array layer to an outside through the substrate.

According to an embodiment of the present disclosure, the display panel 110 may include a pixel array part disposed in a pixel area configured by a plurality of gate lines and/or a plurality of data lines. The pixel array part may include a plurality of pixels that display an image based on a signal supplied to the signal lines. The signal lines may include a gate line, a data line, a pixel driving power line, and the like.

Each of the plurality of pixels may include a pixel circuit layer including a driving thin film transistor provided in the pixel area, an anode electrode electrically connected to the driving thin film transistor, a light emitting layer formed on the anode electrode, and a cathode electrode electrically connected to the light emitting layer.

The driving thin film transistor may be configured at a transistor region of each pixel region disposed on the substrate. The driving thin film transistor may include a gate electrode, a gate insulating layer, a semiconductor layer, a source electrode, and a drain electrode. The semiconductor layer of the driving thin film transistor may include silicon such as a-Si, poly-Si, or low temperature poly-Si, or may include an oxide such as indium-gallium-zinc-oxide (IGZO) or the like, but is not limited thereto.

The anode electrode may be provided at an opening area disposed in each pixel area to be electrically connected to the driving thin film transistor.

The light emitting layer according to the embodiment of the present disclosure may include an organic light emitting device formed on an anode electrode. The organic light emitting device may be implemented to emit light of a same color for each pixel, for example, white, or may be implemented to emit light of one or more of different colors, for example, red, green, and blue for each pixel.

The light emitting layer according to another embodiment may include a micro light emitting diode device electrically connected to each of an anode electrode and a cathode electrode. The micro light emitting diode device is a light emitting diode implemented in the form of an integrated circuit (IC) or a chip, and may include a first terminal electrically connected to the anode electrode and a second terminal electrically connected to the cathode electrode. The cathode electrode may be commonly connected to the light emitting device (or the micro light emitting diode device) of the light emitting layer provided in each pixel area.

Since an encapsulation part is formed on the substrate to surround the pixel array part, oxygen or moisture may be prevented from penetrating into the light emitting layer of the pixel array part. The encapsulation part according to an embodiment may be formed in a multilayer structure in which organic material layers and inorganic material layers are alternately stacked, but is not limited thereto. The inorganic material layer may block oxygen or moisture from penetrating into the light emitting device layer of the pixel array area. The organic material layer may be formed to have a relatively thicker thickness than the inorganic material layer so as to cover particles (or foreign substances) that may occur during the manufacturing process. For example, the encapsulation part may include a first inorganic layer, an organic layer on the first inorganic layer, and a second inorganic layer on the organic layer. The organic layer may be a particle cover layer. A touch panel may be disposed on the encapsulation part or on a rear surface of the pixel array part.

According to an embodiment of the present disclosure, the display panel 110 may include an upper substrate, a lower substrate, and a liquid crystal layer. The upper substrate is a first substrate or a thin film transistor array substrate, and may include a pixel array (or a display part or a display area) having a plurality of pixels formed in a pixel area intersected by a plurality of gate lines and/or a plurality of data lines. Each of the plurality of pixels may include a thin film transistor connected to a gate line and/or a data line, a pixel electrode connected to the thin film transistor, and a common electrode formed to be adjacent to the pixel electrode to supply a common voltage.

The upper substrate may further include a pad part provided at a first edge (or first non-display part) and a gate driving circuit provided at a second edge (or second non-display part).

The pad part may supply a signal supplied from the outside to the pixel array and/or the gate driving circuit. For example, the pad part may include a plurality of data pads connected to the plurality of data lines through a plurality of data link lines and/or a plurality of gate input pads connected to the gate driving circuit through a gate control signal line. For example, a size of the upper substrate may be greater than that of the lower substrate, but is not limited thereto.

The gate driving circuit may be embedded (or integrated) in the second edge of the upper substrate to be connected to the plurality of gate lines. For example, the gate driving circuit may be implemented as a shift register including a transistor formed by a same process as the thin film transistor provided in the pixel area. The gate driving circuit according to another embodiment may be implemented in the form of an integrated circuit (IC) without being embedded in the upper substrate and included in a panel driving circuit.

The lower substrate may be a second substrate or a color filter array substrate. The lower substrate may include a pixel pattern including an opening area overlapping a pixel area formed in the upper substrate, and a color filter layer formed in the opening area. The lower substrate may have a size smaller than that of the upper substrate, but is not limited thereto. For example, the lower substrate may overlap the remaining portions except for the first edge of the upper substrate. The lower substrate may be bonded to the remaining portions except for the first edge of the upper substrate by a sealant with a liquid crystal layer interposed therebetween.

The liquid crystal layer may be interposed between the upper substrate and the lower substrate. The liquid crystal layer may be formed of a liquid crystal in which the arrangement direction of the liquid crystal molecules is changed according to a data voltage applied to the pixel electrode for each pixel and an electric field formed by the common voltage.

According to an embodiment of present disclosure, the display panel 110 may display an image according to light passing through the liquid crystal layer by driving the liquid crystal layer according to the data voltage applied for each pixel and the electric field formed for each pixel by the common voltage.

In the display panel 110, the upper substrate may be the color filter array substrate, and the lower substrate may be the thin film transistor array substrate. For example, the display panel 110 according to another embodiment of the present disclosure may have a shape in which the display panel 110 according to an embodiment of the present disclosure is inverted vertically. In this case, the pad part of the display panel 110 according to another embodiment of the present disclosure may be covered by a separate structure.

The display panel 110 may include a bending portion that is bent or curved to have a curved shape or a constant radius of curvature.

The bending portion of the display panel 110 may be implemented on at least one of one edge portion and the other edge parallel to each other in the display panel 110. One edge and/or the other edge of the display panel 110 implementing the bending portion may include only the non-display area, or may include an edge of the display area and the non-display area. For example, the display panel 110 including the bending portion implemented by bending of the non-display area may have a one-sided bezel bending structure or a two-sided bezel bending structure. In addition, the display panel 110 including the bending portion implemented by bending of an edge of the display area and the non-display area may have a one-sided active bending structure or a two-sided active bending structure.

The functional film 130 may be disposed or configured over the display panel 110. The functional film 130 may be disposed or configured at a second surface different from the first surface of the display panel 110. The functional film 130 may be attached onto the display panel 110 bay using a transparent adhesive member. For example, the adhesive member may include a pressure sensitive adhesive PSA, an optical cleared adhesive OCA, or an optical cleared resin OCR, but is not limited thereto.

According to an embodiment of the present disclosure, the functional film 130 may include an anti-reflection layer (or an anti-reflection film) for improving outdoor visibility and contrast ratio of an image displayed on the display panel 110 by preventing reflection of external light. For example, the anti-reflection layer may include a circular polarization layer (or a circular polarization film) that blocks the reflected light reflected by the thin film transistor and/or lines disposed on the pixel array layer of the display panel 110 from traveling to the outside.

The functional film 130 may further include an optical path control layer (or an optical path control film) that controls a path of light emitted from the pixel array layer of the display panel 110 to the outside. The optical path control layer may include a structure in which high and low refractive layers are alternately stacked, and thus, it is possible to minimize a color shift phenomenon according to a viewing angle by changing the path of light incident from the pixel array layer. For example, the low refractive layer may be disposed at the uppermost layer of the optical path control layer, but is not limited thereto.

According to an embodiment of the present disclosure, the vibration member 100 may further include a touch electrode part for a user interface using a user touch. The touch electrode part may be interposed between the display panel 110 and the functional film 130 or may be embedded in the display panel 110 according to an in-cell touch method. For example, the touch electrode part according to the in-cell touch type may include touch electrodes of a mutual capacitance type or touch electrodes of a self-capacitance type.

According to an embodiment of the present disclosure, the vibration driving apparatus 10 may further include a cover member 300. The cover member 300 may be disposed at a rear surface of the vibration member 100. The cover member 300 may support the vibration member 100. For example, the cover member 300 may be connected to the vibration apparatus 500 to support or fix the vibration apparatus 500.

The cover member 300 may be represented by a cover bottom, a plate bottom, a back cover, a set cover, a rear cover, a rear frame, a base frame, a metal frame, a metal chassis, a chassis base, a chassis, an m-chassis, or the like. Accordingly, the cover member 300 may be implemented as any type of frame or plate-shaped structure disposed at the rear surface of the vibration member 100. The rear surface of the vibration member 100 may be represented by one surface, a first surface, a rear surface, a lower surface, or the like, but is not limited thereto.

According to an embodiment of the present disclosure, the cover member 300 may include a first cover member 310 and a second cover member 350.

The first cover member 310 may be disposed at the rear surface of the vibration member 100. The first cover member 310 may be spaced apart from a rearmost surface of the vibration member 100 with a gap space GS therebetween. The first cover member 310 may protect the rear surface of the vibration member 100 from an external impact. The first cover member 310 may reinforce the rigidity of the cover member 300 and perform a heat dissipation function. For example, the first cover member 310 may be an inner plate, a rigid plate, or a heat dissipation plate (or heat sink). For example, the first cover member 310 may be formed of a glass material, a metal material, or a plastic material. For example, the glass material may have one or more of sapphire glass and gorilla glass, or a stacked structure (or a bonded structure) thereof. For example, the metal material may have one or more of aluminum, an aluminum alloy, a magnesium alloy, an alloy of iron and nickel, and stainless steel, an alloy material thereof, or a bonded structure thereof.

The second cover member 350 may be disposed at a rear surface of the first cover member 310. For example, the second cover member 350 may cover the rear surface of the first cover member 310. The second cover member 350 may be a plate-shaped member that covers an entire rear surface of the first cover member 310. For example, the second cover member 350 may be formed of one or more of a glass material, a metal material, and a plastic material. For example, the second cover member 350 may be formed of a material different from that of the first cover member 310, but is not limited thereto. For example, the second cover member 350 may have a same thickness as that of the first cover member 310 or may be relatively thinner than that of the first cover member 310. For example, in order to more stably support the vibration apparatus 500 and reduce the weight of the vibration driving apparatus 10, the first cover member 310 may have a relatively thicker thickness than that of the second cover member 350.

According to an embodiment of the present disclosure, the vibration driving apparatus 10 may include at least one vibration apparatus 500. The at least one vibration apparatus 500 may be configured to vibrate the vibration member 100. The vibration apparatus 500 may be connected to the rear surface or the first surface 100a of the vibration member 100. Accordingly, sound or vibration may be generated on a front surface (or a front direction) of the vibration member 100.

The vibration apparatus 500 may include a first vibration apparatus 500-1 and a second a vibration apparatus 500-2 disposed in parallel on the first surface of the vibration member 100. The vibration driving apparatus 10 may include the first vibration apparatus 500-1 disposed in a first area (or left area) of the vibration member 100 and the second vibration apparatus 500-2 disposed in a second area (or right area) of the vibration member 100 with respect to a center of the rear surface of the vibration member 100.

For example, the first vibration apparatus 500-1 may vibrate a first rear area of the vibration member 100 to generate sound PVS due to vibration in the first area (or left area) of the vibration member 100. The second vibration apparatus 500-2 may vibrate a second rear area of the vibration member 100 to generate sound PVS due to vibration in the second area (or right area) of the vibration member 100. For example, the vibration driving apparatus 10 may output sound in a two-channel form by left and right sound separation through the first vibration apparatus 500-1 and the second vibration apparatus 500-2. The first vibration apparatus 500-1 may be configured to output a left sound, and the second vibration apparatus 500-2 may be configured to output a right sound.

According to an embodiment of the present disclosure, the first vibration apparatus 500-1 and the second vibration apparatus 500-2 may be a same vibration apparatus. The first vibration apparatus 500-1 and the second vibration apparatus 500-2 may have a same structure. Each of the first vibration apparatus 500-1 and the second vibration apparatus 500-2 may be a vibration apparatus in which a sound generating module 510 and a vibration module 550 are integrated. In the embodiment of the present disclosure, the present disclosure has been described by using two vibration apparatus as an example, but the number of vibration apparatus 500 may be variously provided and may be variously arranged according to a size of the vibration member 100.

According to an embodiment of the present disclosure, the vibration apparatus 500 may include a sound generating structure 510 (also referred to as “a sound generating module 510”), at least one vibration structure 550 (also referred to as “at least one vibration module 550”), and a supporting member 570.

The sound generating module 510 may be disposed or configured at the rear surface or the first surface 100a of the vibration member 100. The sound generating module 510 may be connected to the rear surface or the first surface 100a of the vibration member 100. The sound generating module 510 may vibrate the vibration member 100. For example, the sound generating module 510 may be configured to vibrate the vibration member 100 based on a current (or a voice current) applied based on Fleming's left-hand rule. The sound generating module 510 may be represented by a sound generating unit, an actuator, an exciter, a transducer, or the like, but is not limited thereto.

The sound generating module 510 may include a base plate 511, a magnet 512, a center pole 513, a bobbin 514, a coil 515, an edge frame 516, and a damper 517. For example, the sound generating module 510 may be a coil type sound generating module including a voice coil.

The base plate 511 may be connected to or fixed to the cover member 300. The base plate 511 may be supported or connected to the cover member 300 by using a connection member 600. For example, the base plate 511 may include an extension portion 511a. The extension portion 511a may protrude in parallel from an outer periphery of the base plate 511. The extension portion 511a may be configured between the vibration member 100 and a partial region of the cover member 300 adjacent to the outer periphery of the base plate 511. The extension portion 511a may overlap the partial region of the cover member 300 adjacent to the base plate 511.

The connection member 600 may be fastened (or coupled) to the partial region of the cover member 300 overlapping the extension portion 511a and the extension portion 511a. Accordingly, the base plate 511 may be connected or fixed to the cover member 300 by using the connection member 600.

The base plate 511 may be a main body of the sound generating module 510. The base plate 511 may support one or more of the magnet 512, the center pole 513, and the edge frame 516. The base plate 511 may include a groove portion for accommodating the magnet 512 and the bobbin 514. For example, the groove portion may be formed to be concave from an upper surface of the base plate 511 to have a circular shape. For example, the base plate 511 may include a plastic material. For example, the base plate 511s may include any one of polycarbonate PC, polyethylene PE, polypropylene PP, polystyrene PS, acrylic PMMA, nylon, and polyamide PA. The base plate 511 may be represented by a lower plate, a base frame, a yoke, but is not limited thereto.

The magnet 512, the center pole 513, the bobbin 514, and the coil 515 may be represented as a magnetic circuit unit or a magnetic vibration unit installed in the base plate 511 to vibrate the vibrating member 100. For example, the magnetic circuit unit may have an external magnetic type or dynamic type structure in which the magnet 512 is disposed outside the coil 515. As another example, the magnetic circuit unit may have an internal magnetic type or micro type structure in which the magnet 512 is disposed inside the coil 515. The sound generating module 510 including the magnetic circuit unit having the internal magnetic type structure may have a small leakage magnetic flux and a small size as a whole. The sound generating module 510 according to an embodiment of the present disclosure may have the external magnetic type or the internal magnetic type structure. In the following description, a case in which the sound generating module 510 has the internal type structure is described as an example.

The magnet 512 may be disposed on (or over) the base plate 511. The magnet 512 may use a sintered magnet such as barium ferrite or the like. The magnet 512 may include one or more of iron trioxide (Fe₂O₃), barium witherite (BaCO₃), neodymium (Nd), strontium ferrite (Fe₁₂O₁₉Sr) with improved magnetic properties, and an alloy cast magnet including aluminum (Al), nickel (Ni), and cobalt (Co), or the like. For example, a neodymium magnet may be neodymium-iron-boron (Nd—Fe—B) or the like, but is not limited thereto.

The center pole 513 may be disposed on (or over) the magnet 512. The center pole 513 may be accommodated or inserted into the bobbin 514 to guide the lifting of the bobbin 514. For example, the center pole 513 may be accommodated or inserted into the bobbin 514, and thus, an outer surface of the center pole 513 may be surrounded by the bobbin 514. The center pole 513 may be represented by an elevation guider, pole pieces, or the like, but is not limited thereto.

The bobbin 514 may be disposed on (or over) the base plate 511. The bobbin 514 may surround around the magnet 512. The bobbin 514 may have a circular shape or an elliptical (or oval) shape, but is not limited thereto. For example, in the bobbin 514 having the oval shape, a ratio of a long-axis diameter to a short-axis diameter may be set to 1.3:1 to 2:1. The bobbin 514 having the oval shape may improve a sound of a high-pitched sound band than a circular shape. The bobbin 514 having the oval shape may decrease the occurrence of heat caused by a vibration, and thus, may have an excellent heat dissipation characteristic. For example, the bobbin 514 may be a structure made of pulp, a paper-processed material, aluminum, magnesium, an alloy thereof, a synthetic resin such as polyimide, or the like. For example, the bobbin 514 may be implemented as a polyimide film having relatively excellent heat dissipation characteristics and relatively light in order to prevent a local image quality defect of the display panel 110 due to heat generated from the coil 515. For example, the polyimide film is excellent in thermal and mechanical strength, and thus reliability of the bobbin 514 may be improved. For example, since polyimide films have excellent heat dissipation properties, there is an effect of reducing the generation of heat due to the vibration of bobbin 514. For example, the polyimide film may be KAPTON, which may be a condensation of pyromellitic dianhydride and 4,4′-oxydianiline.

The coil 515 may be wound to surround an outer circumference surface of the bobbin 514 and may be supplied with a sound-generating current (or a voice current) from the outside. For example, the coil 515 may be lifted together (or lowered or raised along) with the bobbin 514. The coil 515 may be a voice coil. For example, when a current is applied to the coil 515, an entire portion of the bobbin 514 may move upward and downward according to Fleming's left hand rule based on an application magnetic field generated around the coil 515 and an external magnetic field generated around the magnet 512. Since the vibration of the display member 110 caused by the up-and-down movement (or vibration) of the bobbin 514, sound PVS or sound waves may be generated from the front surface FD of the vibration member 100.

The coil 515 may be made of a material having relatively excellent heat dissipation characteristics. For example, the coil 515 may have a relatively good heat dissipation characteristic because thermal conductivity thereof is better than that of copper which is a material of a general coil, and may include an Al material which has a relatively good heat dissipation characteristic and is relatively lightweight compared to copper. Accordingly, the sound generating module 510 according to an embodiment of the present disclosure may prevent the occurrence of image quality defects in the display panel 110 by transferring heat generated from the coil 515 to the bobbin 514.

The damper 517 may be configured between the base plate 511 and the bobbin 514. One side of the damper 517 may be connected to the base plate 511, and the other end of the damper 517 may be connected to an outer surface of the bobbin 514. The damper 517 may have a creased structure between one side and the other side thereof and may be contracted and relaxed based on a vertical motion of the bobbin 514 to adjust a vibration of the bobbin 514. The damper 517 is connected between the base frame 511 and the bobbin 514 and may limit a vibration distance of the bobbin 514 through a restoring force. For example, when the bobbin 514 vibrates by a certain distance or more or vibrates by a certain distance or less, the bobbin 514 may be restored to an original position by the restoring force of the damper 517. For example, the damper 517 may include a metal material electrically connected to the coil 515. For example, the damper 517 may be made of stainless steel, copper (Cu), or the like, but is not limited thereto. The damper 517 may be expressed in other terms such as a spider, a suspension, an edge, or the like, but is not limited thereto.

The edge frame 516 may be installed on a front surface of the base plate 511 and may support the damper 517. The edge frame 516 may be formed at a front edge of the base plate 511 to have a certain height.

A first adhesive member 410 may be configured between the vibration member 100 and the sound generating module 510. For example, the vibration member 100 and the sound generating module 510 may be connected to each other by using the first adhesive member 410. The first adhesive member 410 may be one or more of a double-sided tape, a double-sided foam tape, a double-sided pad, a double-sided foam pad, a single-side tape, a single-sided foam tape, a single-sided pad, a single-sided foam pad, an adhesive, and a bond, but is not limited thereto.

The vibration driving apparatus 10 according to an embodiment of the present disclosure may include at least one vibration module 550. The vibration driving apparatus 10 according to an embodiment of the present disclosure may include one vibration module 550.

The vibration module 550 may be configured between the vibration member 100 and the sound generating module 510. The vibration module 550 may be configured between the vibration member 100 and the base plate 511. The vibration module 550 may be connected to the rear surface or the first surface 100a of the vibration member 100. The vibration module 550 may be connected to the sound generating module 510. The vibration module 550 may be configured at one side or the other side of the base plate 511 to be spaced apart from the magnet 512, the bobbin 514, and the coil 515. For example, as the vibration apparatus 500 is connected to the cover member 300 by using the connection member 600, a first space S1 may be generated at the one side or the other side between the vibration member 100 and the base plate 511. The vibration module 550 may be disposed in a first space S1 between the vibration member 100 and the base plate 511.

According to an embodiment of the present disclosure, the vibration module 550 may have a structure different from that of the sound generating module 510. For example, the vibration module 550 may include a film-type vibration module. For example, the vibration module 550 may include a piezoelectric material, a composite piezoelectric material, or an electroactive material, that has a piezoelectric effect.

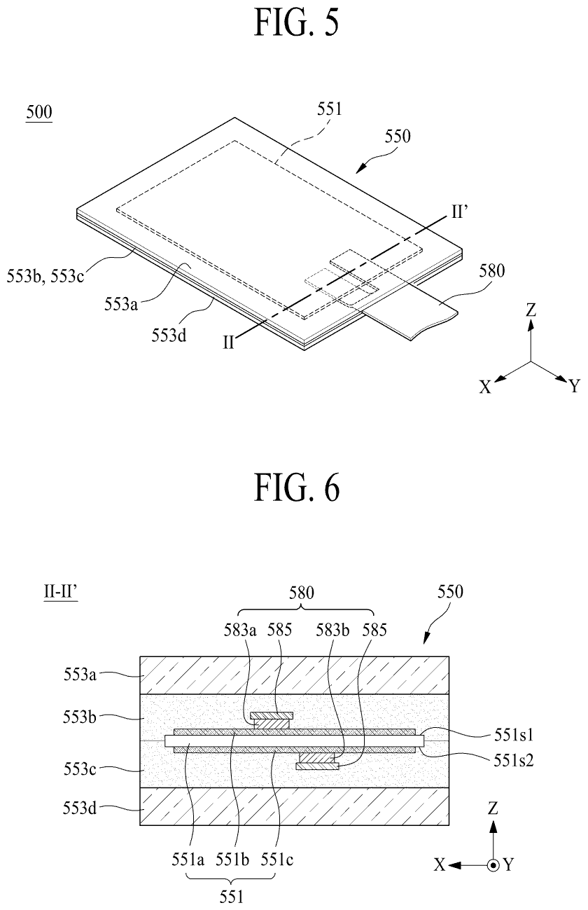

The vibration module 550 may be connected to a signal supply member. The signal supply member may be electrically connected to a pad portion disposed at the vibration module 550 and may supply a vibration driving signal (or a sound signal) provided from the vibration driving part to the vibration module 550. Hereinafter, detailed configurations of the vibration module 550 and the signal supply member will be described in detail with reference to FIGS. 5 and 6.

According to an embodiment of the present disclosure, the vibration apparatus 500 may include a supporting member 570. The supporting member 570 may be configured between the vibration module 550 and one side of the sound generating module 510. The supporting member 570 may be connected to the sound generating module 510 and the vibration module 550. The supporting member 570 may be configured between the vibration module 550 and the base plate 511.

The supporting member 570 may support the vibration module 550. The vibration module 550 may be coupled or integrated with the sound generating module 510 by using the supporting member 570. For example, the supporting member 570 may have a size equal to or smaller than that of the vibration module 550, but is not limited thereto. For another example, the supporting member 570 may have a size greater than that of the vibration module 550. For example, the size of the supporting member 570 may be 10% or more of that of the vibration module 550, and the size of the supporting member 570 may be set within a range that is not in contact with the edge frame 516.

Accordingly, the supporting member 570 may be easily connected the vibration module 550 to the sound generating module 510 while supporting the rear surface of the vibration module 550. The supporting member 570 according to an embodiment of the present disclosure may be configured to cover an entire rear surface or a part of the rear surface of the vibration module 550.

According to an embodiment of the present disclosure, the supporting member 570 may be a foam tape having elasticity and adhesive force. The supporting member 570 may be one or more of a double-sided tape, a double-sided foam tape, a double-sided foam pad, a single-sided foam tape, a single-sided pad, a single-sided foam pad, an adhesive, and a bond, but is not limited thereto. For example, the supporting member 570 may include any one of PE/Acrylic (Polyethylene/Acrylic), PE-EVA/Acrylic (Ethylene Vinyl Acetate/Acrylic), Polyolefin (PO), Thermoplastic Elastomer (TPE), Polyurethane (TPU/PU), Acrylic (PMMA), Silicone and Silicone Rubber, Acrylonitrile Butadiene Styrene (ABS), Nylon, Polyamide, Polycarbonate (PC), Polyethylene (PE), and Polystyrene (PS).

The supporting member 570 may have a thickness greater than a distance D1 between the vibration module 550 and the base plate 511. For example, since the supporting member 570 includes a material having elasticity, the supporting member 570 may have a thickness greater than a distance D1 between the vibration module 550 and the base plate 511 in order to easily adhere the vibration module 550 to the vibration member 100. Accordingly, before attaching the vibration apparatus 500 to the vibration member 100, an uppermost surface of the vibration module 550 may be positioned higher than an uppermost surface of the sound generating module 510. For example, before attaching the vibration apparatus 500 to the vibration member 100, an uppermost surface of the vibration module 550 may be positioned 0.2 mm to 0.5 mm higher than an uppermost surface of the sound generating module 510. For example, after attaching the vibration apparatus 500 to the vibration member 100, an uppermost surface of the vibration module 550 may be positioned on a same line as an uppermost surface of the sound generating module 510. Accordingly, the vibration module 500 may be easily attached to the first surface 100a of the vibration member 100.

Since the vibration driving apparatus 10 according to the embodiment of the present disclosure includes the supporting member 570, the vibration module 550 may be easily coupled to the first surface 100a of the vibration member 100 and the sound generating module 510. In addition, the vibration apparatus 500 in which the vibration module 550 and the sound generating module 510 are integrated may be implemented.

According to an embodiment of the present disclosure, a second adhesive member 420 may be configured between the vibration member 100 and the vibration module 550. For example, the vibration member 100 and the vibration module 550 may be connected by using the second adhesive member 420. The second adhesive member 420 may include a same material as that of the first adhesive member 410, but is not limited thereto.

According to an embodiment of the present disclosure, the vibration driving apparatus 10 may further include a connection member 600. The connection member 600 may penetrate the cover member 300 and the base plate 511, and may be configured to connect or fix the vibration apparatus 500 to the cover member 300.

Accordingly, the connection member 600 may be configured at a partial region of the cover member 300 overlapping the extension portion 511a and the extension portion 511a of the base plate 511. The connection member 600 may be configured to penetrate the partial region of the cover member 300 overlapping the extension portion 511a and the extension portion 511a. The connection member 600 may be fastened to the partial region of the cover member 300 overlapping the extension portion 511a and the extension portion 511a.

According to an embodiment of the present disclosure, the connection member 600 may include a screw member 610 and a nut member 630. The screw member 610 may be configured to penetrate an extension portion 511a and the partial region of the cover member 300 overlapping the extension portion 511a. The nut member 630 may be configured on the base plate 511 and fastened to the screw member 610.

The vibration apparatus 500 may be easily fastened to the cover member 300 by the screw member 610 and the nut member 630. For example, the nut member 630 may be a self-clinching nut or a PEM nut, and embodiments are not limited thereto. When the self-clinching nut is used, vibration generated in the vibration apparatus 500 may be partially absorbed by the self-clinching nut, and thus, vibration transmitted to the cover member 300 may be reduced.

According to an embodiment of the present disclosure, the vibration driving apparatus 10 may further include a middle frame 700.

The middle frame 700 may be disposed between a rear edge of the vibration member 100 and a front edge of the cover member 300. The middle frame 700 may support edges of each of the vibration member 100 and the cover member 300. The middle frame 700 may surround each side surface of at least one or more of the vibration member 100 and the cover member 300. A gap space GS may be provided between the vibration member 100 and the cover member 300 by the middle frame 700. The gap space GS may be expressed as an air gap, a vibration space, a vibration apparatus arrangement space, or the like, but is not limited thereto.

According to an embodiment of the present disclosure, the middle frame 700 may be formed of a metal material or a plastic material. For example, the middle frame 700 may be formed of a metal material to improve a side exterior design of the display apparatus and to protect the side surface of the display apparatus.

The middle frame 700 may be connected to or coupled to the rear edge of the vibration member 100 by using a first coupling member 707. The middle frame 700 may be connected to or coupled to the front edge of the cover member 300 by using a second coupling member 708. The front surface of the cover member 300 may be the other surface, the second surface, the upper surface, or the like, but is not limited thereto. The middle frame 700 may be expressed as a middle cabinet, a middle cover, a middle chassis, or the like, but is not limited thereto. Alternatively, the middle frame 700 may be integrally formed with the second cover member 350 and may be expressed as a second cover member 350.

According to an embodiment of the present disclosure, the middle frame 700 may include a supporting portion 710 and a sidewall portion 730. For example, the supporting portion 710 may be a first portion, and the sidewall portion 730 may be a second portion.

The supporting portion 710 may have a single frame structure of a tetragonal shape, but is not limited thereto. For example, the supporting portion 710 may have a shape of a plurality of division bars interposed in a region between the rear edge of the vibration member 100 and the front edge of the cover member 300.

The supporting portion 710 may be interposed in a region between the rear edge of the vibration member 100 and the front edge of the cover member 300, and thus, the gap space GS may be provided between the vibration member 100 and the cover member 300. A front surface of the supporting portion 710 may be connected to the rear edge of the vibration member 100 by using the first coupling member 707. A rear surface of the supporting portion 710 may be connected to the front edge of the cover member 300 by using the second coupling member 708. For example, the thickness of the supporting portion 710 may be set based on a thickness of the vibration apparatus 500 disposed between the vibration member 100 and the cover member 300, a thickness of the first coupling member 707, and a thickness of the second coupling member 708.

The first coupling member 707 may be disposed in the region between the rear edge of the vibration member 100 and the front surface of the supporting portion 710. For example, the first coupling member 707 may be an adhesive resin, a double-sided tape, or a double-sided adhesive foam pad, but is not limited thereto.

The second coupling member 708 may be disposed in the region between the front edge of the vibration member 300 and the rear surface of the supporting portion 710. For example, the second coupling member 708 may be an adhesive resin, a double-sided tape, or a double-sided adhesive foam pad, but is not limited thereto. For example, the first coupling member 707 and the second coupling member 708 may be formed of a same material or different materials.

The sidewall portion 730 may be vertically coupled to an outer side surface of the supporting portion 710 in parallel with a thickness direction Z of the vibration driving apparatus 10. The sidewall portion 730 may surround both an outer side surface (or outer sidewall) of the vibration member 100 and an outer side surface (or outer sidewall) of the cover member 300. Accordingly, sidewall portion 730 may protect the outer side surface of each of the vibration member 100 and the cover member 300, and may improve an outer design of side surfaces of the vibration driving apparatus 10.

The vibration driving apparatus 10 according to another embodiment of the present disclosure may include an adhesive member instead of the middle frame 700. The adhesive member may be interposed in the region between the rear edge of the vibration member 100 and the front edge of the cover member 300, and thus, the gap space GS may be provided between the vibration member 100 and the cover member 300.

Accordingly, the vibration driving apparatus 10 according to an embodiment of the present disclosure may output the sound PVS to the front surface (or a front direction) FD of the display panel 100 by one or more vibration apparatuses 500 disposed in the region between the vibration member 100 and the cover member 300, thereby enhancing an immersion experience of a viewer watching an image displayed by the display apparatus.

In addition, in the vibration driving apparatus 10 according to an embodiment of the present disclosure, since the sound PVS is generated based on a vibration of the display panel 110, a separate speaker may not be provided, thereby enhancing a design of a set apparatus and a degree of freedom in disposition of elements.

The vibration driving apparatus 10 according to the embodiment of the present disclosure includes the vibration apparatus 500 in which the sound generating module 510 and the vibration module 550 are integrated, and thus, sound characteristics and/or sound pressure level characteristics of middle-low-pitched sound band and middle-high-pitched sound band may be improved.

In addition, the vibration driving apparatus 10 according to the embodiment of the present disclosure includes the vibration apparatus 500 in which the sound generating module 510 and the vibration module 550 are integrated, and thus, sound characteristics and/or sound pressure level characteristics of similar middle-low-pitched sound band and middle-high-pitched sound band may be implemented at all attachment locations of the vibration apparatus 500.

In addition, the vibration driving apparatus 10 according to the embodiment of present disclosure includes a vibration apparatus 500 in which the sound generating module 510 and the vibration module 550 are integrated, and thus, multi-panel sound may be implemented, and there is the effect of uni materialization.

In addition, the vibration driving apparatus 10 according to the embodiment of present disclosure includes the vibration apparatus 500 in which the sound generating module 510 and the vibration module 550 are integrated, and thus, the structure of the vibration driving apparatus 10 may be simplified and manufacturing costs may be reduced.

FIG. 5 is a diagram illustrating a vibration module according to an embodiment of the present disclosure. FIG. 6 is a cross-sectional view taken along line II-II′ illustrated in FIG. 5. FIGS. 5 and 6 illustrate the vibration module and the signal supply member of the vibration apparatus described above with reference to FIGS. 1 to 4.

Referring to FIGS. 5 and 6, the vibration module 550 according to an embodiment of the present disclosure may include a piezoelectric material having piezoelectric characteristics. The vibration module 550 may be formed of a ceramic-based piezoelectric material capable of implementing relatively strong vibration, or may be formed of a piezoelectric ceramic having a perovskite-based crystal structure. For example, the vibration module 550 may be a vibration generating device, a vibration film, a vibration generating film, a vibrator, a vibration generator, an active vibrator, an active vibration generator, an actuator, an exciter, a film actuator, a film exciter, an ultrasonic actuator, or an active vibration member, or the like, but embodiments of the present disclosure are not limited thereto.

The vibration module 550 according to an embodiment of the present disclosure may include a vibration generating part 551.

The vibration generating part 551 may be configured to vibrate by a piezoelectric effect according to a driving signal. The vibration generating part 551 may include at least one or more of a piezoelectric inorganic material and a piezoelectric organic material. For example, the vibration generating part 551 may be a vibration device, a piezoelectric device, a piezoelectric device part, a piezoelectric device layer, a piezoelectric structure, a piezoelectric vibration part, a piezoelectric vibration layer, or the like, and embodiments of the present disclosure are not limited thereto.

The vibration generating part 551 according to an embodiment of the present disclosure may include a vibration layer 551a, a first electrode layer 551b, and a second electrode layer 551c.

The vibration layer 551a may include a piezoelectric material or an electroactive material having a piezoelectric effect. For example, the piezoelectric material may have a characteristic in which, when pressure or twisting phenomenon is applied to a crystalline structure by an external force, a potential difference occurs due to dielectric polarization caused by a relative position change of a positive (+) ion and a negative (−) ion, and thus a vibration is generated by an electric field based on a reverse voltage applied thereto. For example, the vibration layer 551a may be a piezoelectric layer, a piezoelectric material layer, an electroactive layer, a piezoelectric composite layer, a piezoelectric composite, a piezoelectric ceramic composite, or the like, and embodiments of the present disclosure are not limited thereto.

The vibration layer 551a may be configured as a ceramic-based material capable of implementing a relatively strong vibration, or may be configured as a piezoelectric ceramic having a perovskite-based crystalline structure. The perovskite crystalline structure may have a piezoelectric effect and/or an inverse piezoelectric effect and may be a plate-shaped structure having orientation or alignment.

The piezoelectric ceramic may be configured as a single crystalline ceramic having a crystalline structure, or may be configured as a ceramic material having a polycrystalline structure or polycrystalline ceramic. The piezoelectric material of the single crystal ceramic may include a lead zirconate titanate PZT-based materials containing lead (Pb), zirconium (Zr), and titanium (Ti), a lead zirconate nickel niobate PZNN materials containing lead (Pb), zirconium (Zr), nickel (Ni), and niobium (Nb), α-AlPO₄, α-SiO₂, LiNbO₃, Tb₂(MoO₄)₃, Li₂B₄O₇, or ZnO, but embodiments of the present disclosure are not limited thereto. The piezoelectric material of the polycrystalline ceramic may include a lead zirconate titanate PZT-based materials containing lead (Pb), zirconium (Zr), and titanium (Ti), or a lead zirconate nickel niobate PZNN materials containing lead (Pb), zirconium (Zr), nickel (Ni), and niobium (Nb), but embodiments of the present disclosure are not limited thereto. For example, the vibration layer 551a may include at least one of CaTiO₃, BaTiO₃, (K,Na)NbO₃, and SrTiO₃, which do not contain lead (Pb), but embodiments of present disclosure are not limited thereto.

The first electrode layer 551b may be disposed at a first surface (or an upper surface or a front surface) 551s1 of the vibration layer 551a. The first electrode layer 551b may have a same size as the vibration layer 551a or may have a smaller size than the vibration layer 551a.

The second electrode layer 551c may be disposed at a second surface (or a lower surface or a rear surface) 551s2 that is different from or opposite to the first surface 551s1 of the vibration layer 551a. The second electrode layer 551c may have a same size as the vibration layer 551a or may have a smaller size than the vibration layer 551a. For example, the second electrode layer 551c may have a same shape as the vibration layer 551a, but embodiments of the present disclosure are not limited thereto.

According to an embodiment of the present disclosure, in order to prevent an electrical connection (or short circuit) between the first electrode layer 551b and the second electrode layer 551c, each of the first electrode layer 551b and the second electrode layer 551c may be formed on an entire portion except for an edge portion of the vibration layer 551a. For example, the first electrode layer 551b may be formed on the entire portion of the remaining portion of the first surface 551s1a except for an edge portion thereof. For example, the second electrode layer 551c may be formed at the entire portion of the second surface 551s2 of the vibration layer 551a except for an edge portion thereof. For example, a distance between a side surface (or outer sidewall) of each of the first electrode layer 551b and the second electrode layer 551c and a side surface (or outer sidewall) of the vibration layer 551a may be at least 0.1 mm or more. For example, a distance between a side surface of each of the first electrode layer 551b and the second electrode layer 551c and a side surface of the vibration layer 551a may be at least 0.5 mm or more, but embodiments of the present disclosure are not limited thereto.

According to an embodiment of the present disclosure, one or more of the first electrode layer 551b and the second electrode layer 551c may be formed of a transparent conductive material, a translucent conductive material, or an opaque conductive material. For example, the transparent or translucent conductive material may include indium tin oxide (ITO) or indium zinc oxide (IZO), but embodiments of the present disclosure are not limited thereto. The opaque conductive material may include gold (Au), silver (Ag), platinum (Pt), palladium (Pd), molybdenum (Mo), magnesium (Mg), carbon (C), copper (Cu), nickel (Ni), silver including a glass frit, or the like, but embodiments of the present disclosure are not limited thereto. For example, each of the first electrode layer 551b and the second electrode layer 551c may include silver (Ag) having a low specific resistance in order to improve electrical characteristics and/or vibration characteristics of the vibration layer 551a. For example, carbon may be a carbon material including carbon black, ketjen black, carbon nanotubes, and graphite, but embodiments of the present disclosure are not limited thereto.

The vibration layer 551a may be polarized (or polling) by a constant voltage applied to the first electrode layer 551b and the second electrode layer 551c in a constant temperature atmosphere or a temperature atmosphere changed from high temperature to room temperature, but embodiments of the present disclosure are not limited thereto. For example, a polarization direction (or a polling direction) formed in the vibration layer 551a may be formed or oriented (or arranged) from the first electrode layer 551b to the second electrode layer 551c, but is not limited thereto. For another example, the polarization direction (or the polling direction) formed in the vibration layer 551a may be formed or oriented (or arranged) from the second electrode layer 551c to the first electrode layer 551b.

The vibration layer 551a may vibrate by alternately repeating contraction and/or expansion by a reverse piezoelectric effect by a driving signal applied to the first electrode layer 551b and the second electrode layer 551c from the outside. For example, the vibration layer 551a may vibrate in a vertical direction (or a thickness direction) and a plane direction by a signal applied to the first electrode layer 551b and the second electrode layer 551c. The vibration layer 551a may be displaced (or vibrated or driven) by contraction and/or expansion in both the plane and the vertical direction, and thus, vibration characteristic including sound characteristics and/or sound pressure level characteristics of the vibration module 550 may be improved.

According to an embodiment of the present disclosure, the vibration module 550 may further include a first cover member 553a and a second cover member 553d.

The first cover member 553a may be disposed at a first surface of the vibration generating part 551. For example, the first cover member 553a may be configured to cover the first electrode layer 551b of the vibration generating part 551. For example, the first cover member 553a may be configured to have a size larger than that of the vibration generating part 551. The first cover member 553a may be configured to protect the first surface of the vibration generating part 551 and the first electrode layer 551b.

The second cover member 553d may be disposed at the second surface of the vibration generating part 551. For example, the second cover member 553d may be configured to cover the second electrode layer 551c of the vibration generating part 551. For example, the second cover member 553d may be configured to have a size larger than that of the vibration generating part 551, and may be configured to have the same size as that of the first cover member 553a. The second cover member 553d may be configured to protect the second surface and the second electrode layer 551c of the vibration generating part 551.

According to an embodiment of the present disclosure, the first cover member 553a and the second cover member 553d may include a same material or different materials. For example, each of the first cover member 553a and the second cover member 553d may be a polyimide film or a polyethylene terephthalate film, but embodiments of the present disclosure are not limited thereto.

The first cover member 553a may be connected to or coupled to the first surface of the vibration generating part 551 or the first electrode layer 551b by using a first adhesive layer 553b. For example, the first cover member 553a may be connected to or coupled to the first surface of the vibration generating part 551 or the first electrode layer 551b by a film laminating process using the first adhesive layer 553b.

The second cover member 553d may be connected to or coupled to the second surface or the second electrode layer 551c of the vibration generating part 551 by using a second adhesive layer 553c. For example, the second cover member 553d may be connected to or coupled to the second surface or the second electrode layer 551c of the vibration generating part 551 by a film laminating process using the second adhesive layer 553c.

According to an embodiment of the present disclosure, each of the first adhesive layer 553b and the second adhesive layer 553c may include an electrical insulating material having an adhesive property, which may be compressed and restored. For example, each of the first adhesive layer 553b and the second adhesive layer 553c may include an epoxy resin, an acrylic resin, a silicone resin, or a urethane resin, but embodiments of the present disclosure are not limited thereto.

The first adhesive layer 553b and the second adhesive layer 553c may be configured between the first cover member 553a and the second cover member 553d to surround the vibration generating part 551. For example, one or more of the first adhesive layer 553b and the second adhesive layer 553c may be configured to surround the vibration generating part 551.

Any one of the first cover member 553a and the second cover member 553d may be connected to or coupled to the vibration member 100 by using the second adhesive member 420 illustrated in FIGS. 2 and 3. For example, the first cover member 553a, the second cover member 553d, the first adhesive layer 553b, and the second adhesive layer 553c may be partially omitted depending on the configuration of the vibration generating part 551. For example, for connection with the vibration member 100, the cover member and the adhesive layer may be configured only on one surface of the vibration generating part 551. For another example, for connection with the vibration member 100, the adhesive layer may be configured only on one surface of the vibration generating part 551.

The vibration apparatus 500 according to an embodiment of the present disclosure may further include a signal supply member 580.

The signal supply member 580 may be configured to supply a driving signal supplied from a driving circuit part to the vibration generating part 551. The signal supply member 580 may be configured to be electrically connected to the vibration generating part 551. The signal supply member 580 may be configured to be electrically connected to the first electrode layer 551b and the second electrode layer 551c of the vibration generating part 551.

A portion of the signal supply member 580 may be accommodated (or inserted) between the first cover member 553a and the second cover member 553d. An end portion (or a terminal portion or one side) of the signal supply member 580 may be disposed or inserted (or accommodated) between one edge portion of the first cover member 553a and one edge portion of the second cover member 553d. One edge portion of the first cover member 553a and one edge portion of the second cover member 553d may accommodate or vertically cover the end portion (or a terminal portion or one side) of the signal supply member 580. Accordingly, the signal supply member 580 may be integrated with the vibration generating part 551. For example, the signal supply member 580 may include a signal cable, a flexible cable, a flexible printed circuit cable, a flexible flat cable, a single-sided flexible printed circuit, a single-sided flexible printed circuit board, a flexible multilayer printed circuit, or a flexible multilayer printed circuit board, but embodiments of the present disclosure are not limited thereto. As another example, the signal supply member 580 may be connected to the vibration generating part 551 by soldering.

The signal supply member 580 according to an embodiment of the present disclosure may include a base member 585, and a plurality of signal lines 583a and 583b. For example, the signal supply member 580 may include a base member 585, a first signal line 583a, and a second signal line 583b.

The base member 585 may include a transparent or opaque plastic material, but embodiments of the present disclosure are not limited thereto. The base member 585 has a constant width in the first direction X and may extend long in the second direction Y crossing the first direction X.

The first and second signal lines 583a and 583b are disposed at a first surface of the base member 585 in parallel with the second direction Y, and may be spaced apart from each other or electrically separated from each other along the first direction X. The first and second signal lines 583a and 583b may be disposed parallel to each other at the first surface of the base member 585. For example, the first and second signal lines 583a and 583b may be formed in a line shape by patterning of a metal layer (or conductive layer) formed or deposited at the first surface of the base member 585.

End portions (or a terminal portion or one side) of the first and second signal lines 583a and 583b may be individually flexed or bent by being separated from each other.

End portions (or a terminal portion or one side) of the first signal line 583a may be electrically connected to the first electrode layer 551b of the vibration generating part 551. For example, an end portion of the first signal line 583a may be electrically connected to at least a portion of the first electrode layer 551b of the vibration generating part 551 at an edge portion of one side of the first cover member 553a. For example, an end portion (or a terminal portion or one side) of the first signal line 583a may be directly electrically connected to at least a portion of the first electrode layer 551b of the vibration generating part 551. For example, an end portion (or a terminal portion or one side) of the first signal line 583a may be directly connected to or in direct contact with the first electrode layer 551b of the vibration generating part 551. Accordingly, the first signal line 583a may supply the first driving signal, which is provided from the vibration driving part, to the first electrode layer 551b of the vibration generating part 551.

End portions (or a terminal portion or one side) of the second signal line 583b may be electrically connected to the second electrode layer 551c of the vibration generating part 551. For example, an end portion of the second signal line 583b may be electrically connected to at least a portion of the second electrode layer 551c of the vibration generating part 551 at an edge portion of one side of the second cover member 553d. For example, an end portion (or a terminal portion or one side) of the second signal line 583b may be directly electrically connected to at least a portion of the second electrode layer 551c of the vibration generating part 551. For example, an end portion (or a terminal portion or one side) of the second signal line 583b may be directly connected to or in direct contact with the second electrode layer 551c of the vibration generating part 551. Accordingly, the second signal line 583b may supply the second driving signal, which is provided from the vibration driving part, to the second electrode layer 551c of the vibration generating part 551.

According to an embodiment of the present disclosure, a portion of the signal supply member 580 or a portion of the base member 585 is disposed or inserted (or accommodated) between the first cover member 583a and the second cover member 583d, and thus, the signal supply member 580 may be integrated with the vibration generating part 551. Accordingly, the vibration generating part 551 and the signal supply member 580 may be configured as a single component, thereby having an effect of uni materialization.

According to an embodiment of the present disclosure, since the first signal line 583a and the second signal line 583b of the signal supply member 580 are integrated with the vibration generating part 551, a soldering process for electrical connection between the vibration generating part 551 and the signal supply member 580 may not be required. Accordingly, the structure and manufacturing process of the vibration module 550 may be simplified. Accordingly, the vibration driving apparatus according to the embodiment of the present disclosure has an effect of improving a harmful process.

According to another embodiment of the present disclosure, the vibration module 500 may include two or more vibration generating part 551. For example, the vibration module 550 may include a first vibration generating part and a second vibration generating part, which are stacked. When the vibration module 500 includes two or more vibration generating parts 551, a connection electrode or the like for connecting the respective vibration generating parts maybe additionally provided between the respective vibration generating parts 551. When the vibration module 500 includes two or more vibration generating parts 551, the electrode layer formed between the respective vibration generating parts 551 may be formed of one common electrode. In order to maximize the amplitude displacement of the vibration module 550 and/or the amplitude displacement of the vibration member, the first vibration generating part and the second vibration generating part may be overlapped or stacked to be displaced (or driven or vibrated) in a same direction. For example, the first vibration generating part and the second vibration generating part may have substantially a same size as each other, but embodiments of the present disclosure are not limited thereto. A configuration of each of the first vibration generating part and the second vibration generating part may be substantially a same as that of the vibration generating part 551.

According to another embodiment of the present disclosure, the vibration module 550 may include two or more vibration generating parts stacked (or overlapping) to vibrate (or displace or drive) in a same direction, and thus, amount of displacement or amplitude displacement may be maximized or increased. Accordingly, the displacement amount (or bending or driving force) or amplitude displacement of the vibration member may be maximized or increased.

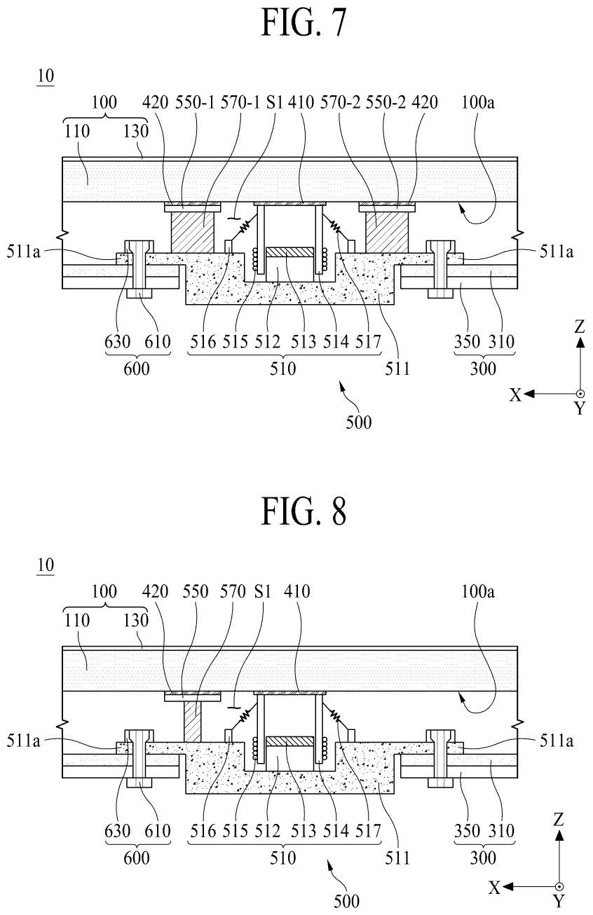

FIG. 7 is a cross-sectional view of a vibration apparatus according to another embodiment of the present disclosure. FIG. 7 illustrates that the vibration driving apparatus according to the embodiment of the present disclosure described above with reference to FIGS. 1 to 4 includes a plurality of vibration modules. Other configurations, except for the plurality of vibration modules are substantially a same as those of the embodiment of the present disclosure. Accordingly, hereinafter, substantially same elements refer to like reference numerals and repeated descriptions are omitted or will be briefly given.

Referring to FIG. 7, the vibration driving apparatus 10 according to another embodiment of the present disclosure may include a plurality of vibration modules 550. For example, the vibration driving apparatus 10 may include a first vibration module 550-1 and a second vibration module 550-2.

According to another embodiment of the present disclosure, each of the first vibration module 550-1 and the second vibration module 550-2 may be configured between the vibration member 100 and the sound generating module 510. Each of the first vibration module 550-1 and the second vibration module 550-2 may be configured between the vibration member 100 and the base plate 511 of the sound generating module 510. Each of the first vibration module 550-1 and the second vibration module 550-2 may be connected to a rear surface or a first surface 100a of the vibration member 100. The first vibration module 550-1 and the second vibration module 550-2 may be connected to the sound generating module 510. According to another embodiment of the present disclosure, the first vibration module 550-1 may be configured between the rear surface or the first surface 100a of the vibration member 100 and one side of the base plate 511. The second vibration module 550-2 may be configured between the rear surface or the first surface 100a of the vibration member 100 and the other side opposite to the one side of the base plate 511. Each of the first vibration module 550-1 and the second vibration module 550-2 may be configured at each of the one side and the other side of the base plate 511 to be spaced apart from the magnet 512, the bobbin 514, and the coil 515. Each of the first vibration module 550-1 and the second vibration module 550-2 may have a same configuration as the vibration module 500 described above with reference to FIGS. 1 to 4.

A second adhesive member 420 may be configured between the vibration member 100 and the first vibration module 550-1 and between the vibration member 100 and the second vibration module 550-2, respectively. For example, the first vibration module 550-1 may be connected to the vibration member 100 by using the second adhesive member (or a 2-1^{th} adhesive member) 420. For example, the second vibration module 550-2 may be connected to the vibration member 100 by using the second adhesive member (or a 2-2^{th} adhesive member) 420.

According to another embodiment of the present disclosure, the vibration apparatus 500 may include a plurality of supporting members 570. Each of a plurality of supporting members 570 may be disposed to correspond to each of the first vibration module 550-1 and the second vibration module 550-2. The plurality of supporting members 570 may include a first supporting member 570-1 and a second supporting member 570-2. The first supporting member 570-1 may support the first vibration module 550-1 at the one side of the vibration member 100 and the base plate 511. The second supporting member 570-2 may support the second vibration module 550-2 at the other side of the vibration member 100 and the base plate 511. The supporting member 570 according to another embodiment of the present disclosure may include a same structure and material as those of the supporting member 570 described above with reference to FIGS. 1 to 4, and thus a same description thereof will be omitted.

According to another embodiment of the present disclosure, the vibration driving apparatus 10 includes the vibration apparatus 500 in which the sound generating module 510 and the plurality of vibration modules 550 are integrated, thereby further improving sound characteristics and/or sound pressure level characteristics of middle-low-pitched sound band and middle-high-pitched sound band.

FIG. 8 is a cross-sectional view of a vibration apparatus according to another embodiment of the present disclosure. FIG. 8 illustrates that the vibration driving apparatus according to an embodiment of the present disclosure described above with reference to FIG. 4 has different configurations of the supporting member. Other configurations except for the supporting member are substantially a same as those of the embodiment of the present disclosure. Accordingly, hereinafter, substantially same elements refer to like reference numerals and repeated descriptions are omitted or will be briefly given.

Referring to FIG. 8, according to another embodiment of the present disclosure, the vibration apparatus 500 according to another embodiment of the present disclosure may include a supporting member 570. The supporting member 570 may be configured between the vibration module 550 and the base plate 511. According to another embodiment of the present disclosure, the supporting member 570 may have a size smaller than that of the vibration module 550. For example, the supporting member 570 may have a size greater than or equal to 10% and less than 100% of the size of the vibration module 550. The supporting member 570 may be disposed at a center of the vibration module 550 to support the vibration module 550. The supporting member 570 may be configured to have various shapes when viewed from above or in a plan view. For example, when viewed from above the vibration module 550, the supporting member 570 may be configured to have a plane of any one of a tetragonal shape, a polygonal shape, a circular shape, and an oval shape.

According to another embodiment of the present disclosure, since the vibration driving apparatus 10 includes the supporting member 570, the vibration module 550 and the sound generating module 510 may be easily coupled. Accordingly, the vibration driving apparatus 10 according to another embodiment of the present disclosure may integrate the vibration module 550 and the sound generating module 510.

In another embodiment of the present disclosure, the vibration driving apparatus 10 according to the present disclosure is described by an embodiment where one supporting member 570 is configured at one vibration module 550, but is not limited thereto. For example, the vibration module 500 may include the first vibration module and the second vibration module as illustrated in FIG. 7, and the supporting member 570 having a smaller size than the vibration module 550 may be configured at each of the first vibration module and the second vibration module. The supporting member 570 configured at each of the first vibration module and the second vibration module includes a same material, and may have a same configuration and a same effect.

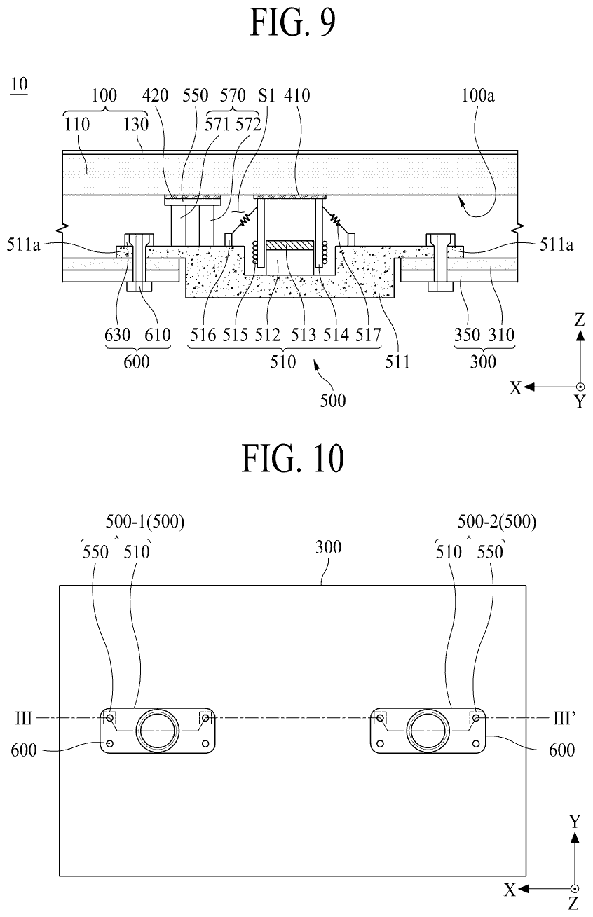

FIG. 9 is a cross-sectional view of a vibration apparatus according to another embodiment of the present disclosure. FIG. 9 illustrates that the vibration driving apparatus according to an embodiment of the present disclosure described above with reference to FIG. 4 has different configurations of the supporting member. Other configurations except for the supporting member are substantially a same as those of the embodiment of the present disclosure. Accordingly, hereinafter, substantially same elements refer to like reference numerals and repeated descriptions are omitted or will be briefly given.

Referring to FIG. 9, the vibration apparatus 500 according to another embodiment of the present disclosure may include a supporting member 570. The supporting member 570 may be configured between the vibration module 550 and the base plate 511.

The supporting member 570 may include a first auxiliary supporting member 571 and a second auxiliary supporting member 572. The vibration module 550 may be connected to one side of the base plate 511 by using the first and second auxiliary supporting members 571 and 572. The first and second auxiliary supporting members 571 and 572 may be disposed in parallel to each other. The first and second auxiliary supporting members 571 and 572 may be spaced apart from each other.

The first auxiliary supporting member 571 may connect a lower surface of one side of the vibration module 550 and an upper surface of one side of the base plate 511. The second auxiliary supporting member 572 may connect a lower surface of the other side which is different from one side of the vibration module 550 and the upper surface of one side of the base plate 511. The first auxiliary supporting member 571 and the second auxiliary supporting member 572 may have a same size and a same shape, but are not limited thereto.

According to another embodiment of the present disclosure, since the vibration driving apparatus 10 includes the supporting member 570, the vibration module 550 and the sound generating module 510 may be easily coupled to each other. Accordingly, the vibration driving apparatus 10 according to another embodiment of the present disclosure may integrate the vibration module 550 and the sound generating module 510.

In another embodiment of the present disclosure, the vibration driving apparatus 10 according to the present disclosure is described by an embodiment where one supporting member 570 is configured at one vibration module 550, but is not limited thereto. For example, the vibration module 500 may include the first vibration module and the second vibration module as illustrated in FIG. 7, and the supporting member 570 including first and second auxiliary supporting members 571 and 572 may be configured at each of the first vibration module and the second vibration module. The supporting member 570 configured at each of the first vibration module and the second vibration module includes a same material and may have a same configuration and a same effect.

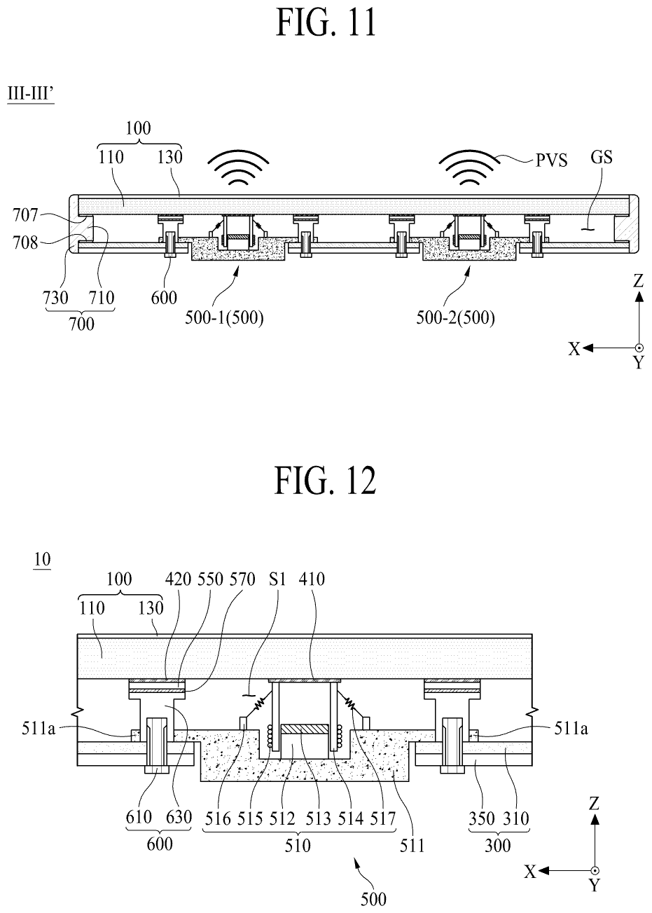

FIG. 10 is a diagram illustrating a vibration driving apparatus according to another embodiment of the present disclosure. FIG. 11 is a cross-sectional view taken along line III-III′ illustrated in FIG. 10. FIG. 12 is a cross-sectional view of the vibration apparatus illustrated in FIG. 11. FIGS. 10 to 12 illustrate that the positions of the vibration module 500 and the supporting member 570 are different in the vibration driving apparatus according to the embodiment of the present disclosure described above with reference to FIGS. 1 to 4. Other configurations except for the vibration module 500 and the supporting member 570 are substantially a same as those of the embodiment of the present disclosure. Accordingly, hereinafter, substantially same elements refer to like reference numerals and repeated descriptions are omitted or will be briefly given.

Referring to FIGS. 10 to 12, the vibration apparatus 500 may be connected or fixed to the cover member 300 by using a connection member 600. The sound generating module 510 and the vibration module 550 may be connected between the vibration member 100 and the cover member 300 by using the connection member 600.

According to another embodiment of the present disclosure, the vibration module 550 may be configured between the vibration member 100 and the base plate 511. The vibration module 550 may be configured between the vibration member 100 and the connection member 600 disposed on the base plate 511. The vibration module 550 may be configured between the vibration member 100 and the nut member 630. The vibration module 550 may be a same as the vibration module described above with reference to FIGS. 5 and 6.

According to another embodiment of the present disclosure, the supporting member 570 may be configured between the vibration module 550 and the connection member 600. The supporting member 570 may be configured between the vibration module 550 and the nut member 630. The vibration module 550 may connect or adhere to the connection member 600 by using the supporting member 570. For example, the supporting member 570 may be a third adhesive member, but is not limited thereto. The supporting member 570 may include a same material as the supporting member 570 described above with reference to FIGS. 1 to 4. However, the present disclosure is not limited thereto, and the supporting member 570 may include a same material as the first adhesive member 410 and the second adhesive member 420.

According to another embodiment of the present disclosure, since the vibration driving apparatus 10 includes the vibration apparatus 500 in which the sound generating module 510 and the vibration module 550 are integrated, thereby further improving sound characteristics and/or sound pressure level characteristics of middle-low-pitched sound band and middle-high-pitched sound band.

According to another embodiment of the present disclosure, the vibration driving apparatus 10 may improve the degree of freedom with respect to the arrangement of the vibration module 550 by arranging the vibration module 550 so as to overlap the connection member 600.

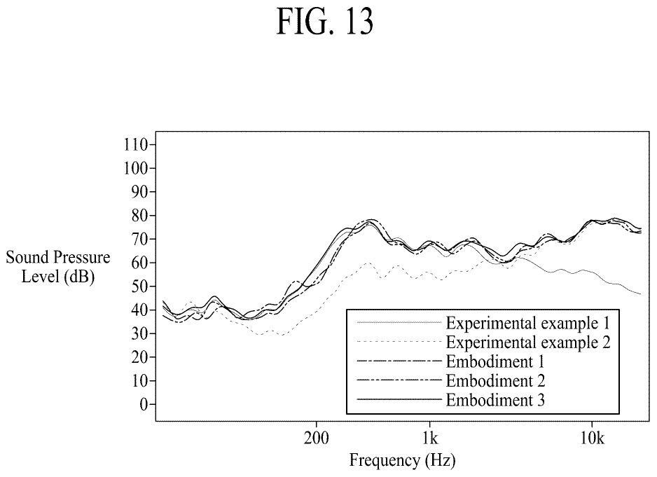

FIG. 13 is a diagram illustrating sound output characteristics of a vibration driving apparatus according to an embodiment of the present disclosure.

The inventors of the present disclosure prepared samples of the vibration driving apparatus according to an experimental example 1, an experimental example 2, and the embodiments 1 to 3 in order to compare the sound pressure level characteristics of the vibration driving apparatus according to the embodiments of the present disclosure. In the drawings, each of a solid line, a dotted line, an alternate long and short dash line, an alternate long and two short dashes line, and a thick solid line represents the sound pressure level characteristics of the experimental example 1, the experimental example 2, and the embodiments 1 to 3. The experimental example 1 illustrates sound pressure level characteristics of the vibration driving apparatus including only the sound generating module, and the experimental example 2 illustrates sound pressure level characteristics of the vibration driving apparatus including only the vibration module. The embodiment 1 illustrates sound pressure level characteristics of the vibration driving apparatus including both the sound generating module and the vibration module described above with reference to FIGS. 1 to 4. The embodiments 2 and 3 illustrate sound pressure level characteristics of the vibration driving apparatus including both the sound generating module and the vibration module described above with reference to FIGS. 8 and 9, respectively.

Referring to FIG. 13, in the frequency range of 2 kHz to 4 kHz, the sound pressure level of each of the experimental example 1, the experimental example 2, and the embodiments 1 to 3 have been measured at 60 dB, 60 dB, 65 dB, 65 dB, and 65 dB. In the frequency range of 4 kHz to 20 kHz, the sound pressure level of each of the experimental example 1, the experimental example 2,and the embodiments 1 to 3 have been measured at 55 dB, 75 dB, 75 dB, 75 dB, and 75 dB.

Comparing with the experimental example 1 including only the sound generating module, it may be seen that the vibration driving apparatus according to the embodiments 1 to 3 of the present disclosure enhanced the sound pressure level characteristics of 15 dB to 20 dB in the frequency range of 2 kHz to 20 kHz.

In the frequency range of 200 kHz to 2 kHz, the sound pressure level of each of the experimental example 1, the experimental example 2, and the embodiments 1 to 3 have been measured at 70 dB, 55 dB, 70 dB, 70 dB, and 70 dB. Comparing with the experimental example 2 including only the vibration module, it may be seen that the vibration driving apparatus according to the embodiments 1 to 3 of the present disclosure enhanced the sound pressure level characteristics of 15 dB in a frequency range of 2 kHz or less.

In the vibration driving apparatus according to the embodiments 1 to 3 of the present disclosure, no sound interference occurred between the sound generating module and the vibration module. That is, in the vibration driving apparatus according to the embodiment of the present disclosure, it was confirmed that the inherent sound pressure level characteristics of each of the sound generating module and the vibration module were maintained. Furthermore, the sound pressure level characteristics of each of the vibration driving apparatuses according to the embodiments 1 to 3 of the present disclosure were measured to be similar. Accordingly, it was confirmed that no significant changes in sound pressure level characteristics appeared due to modifications in the size of the supporting member.

According to an embodiment of the present disclosure, since the vibration driving apparatus 10 includes the vibration apparatus 500 in which the sound generating module 510 and the vibration module 550 are integrated, and thus, it was confirmed that the sound characteristics and/or the sound pressure level characteristics of middle-low-pitched sound band and middle-high-pitched sound band are improved.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure. It will be apparent to those skilled in the art that various modifications and variations may be made in the present disclosure without departing from the spirit or scope of the disclosures. Thus, it is intended that the present disclosure covers the modifications and variations of this disclosure provided they come within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A vibration driving apparatus, comprising:
a vibration member having a first surface; and
a vibration apparatus configured to vibrate the vibration member,
wherein the vibration apparatus includes:
a sound generating structure; and
at least one vibration structure connected to the sound generating structure.

2. The vibration driving apparatus of claim 1, wherein each of the sound generating structure and the vibration structure is connected to the first surface of the vibration member.

3. The vibration driving apparatus of claim 1, further comprising a supporting member configured between one side of the sound generating structure and the vibration structure to support the vibration structure.

4. The vibration driving apparatus of claim 3, wherein the supporting member connects the sound generating structure and the vibration structure.

5. The vibration driving apparatus of claim 3, wherein the supporting member has a size equal to or smaller than that of the vibration structure.

6. The vibration driving apparatus of claim 3, wherein the supporting member includes a first auxiliary supporting member and a second auxiliary supporting member configured to be parallel to each other on a first surface of the vibration structure.

7. The vibration driving apparatus of claim 3, wherein the supporting member includes any one of PE/Acrylic (Polyethylene/Acrylic), PE-EVA/Acrylic (Ethylene Vinyl Acetate/Acrylic), Polyolefin (PO), Thermoplastic Elastomer (TPE), Polyurethane (TPU/PU), Acrylic (PMMA), Silicone and Silicone Rubber, Acrylonitrile Butadiene Styrene (ABS), Nylon, Polyamide, Polycarbonate (PC), Polyethylene (PE), and Polystyrene (PS), and a foam tape having adhesive force.

8. The vibration driving apparatus of claim 1, wherein the sound generating structure includes a coil-type sound generating module.

9. The vibration driving apparatus of claim 1, wherein the vibration structure includes a piezoelectric material.

10. The vibration driving apparatus of claim 1, further comprising an adhesive member between the vibration member and the vibration apparatus.

11. The vibration driving apparatus of claim 3, wherein the sound generating structure includes:
a base plate;
a magnet on the base plate;
a bobbin surrounding the magnet; and
a coil wound around the bobbin,
wherein the vibration structure is configured between the vibration member and the base plate.

12. The vibration driving apparatus of claim 11, wherein the supporting member is configured between the vibration structure and the base plate.

13. The vibration driving apparatus of claim 11, wherein the vibration structure includes one vibration module, and is configured at one side of the base plate to be spaced apart from the magnet, the bobbin, and the coil.

14. The vibration driving apparatus of claim 11, wherein the vibration structure includes:
a first vibration module configured at one side of the base plate to be spaced apart from the magnet, the bobbin, and the coil; and
a second vibration module configured at the other side of the base plate to be spaced apart from the magnet, the bobbin, and the coil.

15. The vibration driving apparatus of claim 1, wherein the vibration structure includes:
a vibration layer including a piezoelectric material;
a first electrode layer at a first surface of the vibration layer; and
a second electrode layer at a second surface different from the first surface of the vibration layer.

16. The vibration driving apparatus of claim 11, further comprising:
a rear cover supporting the vibration member at the first surface of the vibration member; and
a plurality of connection members connecting the rear cover and the sound generating structure.

17. The vibration driving apparatus of claim 16, wherein:
the base plate further includes an extension portion extending from a lateral side of the base plate to overlap with the rear cover, and
the plurality of connection members are configured at the extension portion.

18. The vibration driving apparatus of claim 17, wherein each of the plurality of connection members includes:
a screw member penetrating the rear cover and the extension portion; and
a nut member fastened to the screw member between the vibration structure and the base plate.

19. The vibration driving apparatus of claim 18, wherein the supporting member is on the base plate and configured between the vibration structure and the nut member.

20. The vibration driving apparatus of claim 1, wherein:
the vibration apparatus includes a first vibration apparatus and a second vibration apparatus disposed parallel to each other at the first surface of the vibration member, and
the first vibration apparatus and the second vibration apparatus are a same vibration apparatus.
